(19) United States
(12) Patent Application Publication
(10) Pub. No.: US 2026/0193785 A1
(43) Pub. Date: Jul. 9, 2026

(54) SEMICONDUCTOR PROCESSING SYSTEMS CONFIGURED FOR PERFORMING PLASMA ENHANCED CHEMICAL VAPOR DEPOSITION PROCESSES AND ASSOCIATED METHODS

(71) Applicant: ASM IP Holding B.V., Almere (NL)

(72) Inventors: Krishnaswamy Mahadevan, Tempe, AZ (US); Kishor Patil, Chandler, AZ (US); Fan Gao, Chandler, AZ (US)

(21) Appl. No.: 19/344,013

(22) Filed: Sep. 29, 2025

Related U.S. Application Data
(60) Provisional application No. 63/701,260, filed on Sep. 30, 2024.

(51) Int. Cl. C23C 16/50; C23C 16/24; C23C 16/458; C23C 16/46; C23C 16/52; C30B 25/10; C30B 25/12; C30B 25/14; C30B 29/06; H01J 37/32; H10P 14/20; H10P 14/24

(52) U.S. Cl. CPC C23C 16/50; C23C 16/24; C23C 16/4583; C23C 16/46; C23C 16/52; C30B 25/105; C30B 25/12; C30B 25/14; C30B 29/06; H01J 37/32449; H01J 37/32522; H10P 14/24; H10P 14/3411; H01J 2237/3321

(57) ABSTRACT

Semiconductor processing systems for depositing an epitaxial layer on a substrate by a plasma enhanced chemical vapor deposition are disclosed. The semiconductor processing system includes a chamber body, a substrate support arranged within the chamber interior, and a plasma generation means configured for generating a reactive species within the chamber interior. Methods for depositing an epitaxial layer on a substrate by a plasma enhanced chemical vapor deposition process are also disclosed.

### CROSS-REFERENCE TO RELATED APPLICATION(S)

This Application claims the benefit of U.S. Provisional Application 63/701,260 filed on Sep. 30, 2024, the entire contents of which are incorporated herein by reference.

### FIELD

The present disclosure generally relates to the field of semiconductor processing systems, associated methods and to the field of device and integrated circuit manufacture. More particularly the present disclosure generally relates to semiconductor processing systems configured for performing plasma enhanced chemical vapor deposition processes and associated methods for depositing one or more epitaxial layers.

### BACKGROUND

In plasma enhanced chemical vapor deposition (PECVD), an epitaxial layer is deposited on a substrate, such as a silicon wafer. After the generation of excited reactive species by a plasma generation device/system, chemical reactions may occur in a reaction chamber, where one or more reactants may react and/or decompose on the substrate surface to produce the epitaxial layer.

To facilitate the occurrence of the chemical reactions, conventional systems may attempt to increase the temperature at which the deposition occurs. However, such approaches may require high energy consumption and/or exceed the thermal budget of certain materials on the substrate thereby causing undesirable effects such as instability and chamber coating. As a result, conventional systems may lack a mechanism to strike a balance between growth rate and thermal budget, and thereby limit their ability to control precursor deposition and provide optimal performance, throughput, and energy consumption in the semiconductor manufacturing process.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments provided include a semiconductor processing system configured for performing plasma enhanced epitaxial deposition processes, the semiconductor processing system comprising: a chamber body having an upper wall, a lower wall, a first side wall and a second side wall opposing the first side wall, wherein the upper wall extends longitudinally between an injection end and a longitudinally opposite exhaust end, and the lower wall is below and parallel relative to the upper wall; a substrate support configured to support a substrate and arranged within a chamber interior between the injection end and the exhaust end; an injection flange comprising a plurality of injection ports coupled to the injection end and configured for introducing a vapor phase process gas into the chamber interior; and a plasma generation means configured for generating a reactive species from the vapor phase process gas within the chamber interior at a plasma generation zone disposed between the injection flange and the substrate support.

In some embodiments, the plasma generation means comprises one or more internal elements disposed within the chamber interior.

In some embodiments, the plasma generation means comprises an internal filament longitudinally positioned between the injection flange and the substrate support.

In some embodiments, the internal filament is positioned proximate to the plurality of injection ports such that the internal filament intersects a flow path of the vapor phase process gas into the chamber interior.

In some embodiments, the internal filament extends perpendicular between the first side wall and the second side wall opposing to the first side wall.

In some embodiments, the internal filament is electrically coupled to an exterior plasma power/control system by a first contact and a second contact both extending through the first side wall from the chamber interior to a chamber exterior.

In some embodiments, the internal filament is supported at the first side wall by a cantilever configuration.

In some embodiments, the internal filament is electrically coupled to a plasma power/control system by a first contact extending through the first side wall and by a second contact extending through the second side wall opposing the first side wall.

In some embodiments, the internal filament is one of a plurality of internal filaments and each one of the plurality of internal filaments is positioned proximate to one of the plurality of injection ports such that each one of the plurality of internal filaments intersects an individual flow path of the vapor phase process gas introduced by one of the plurality of injection ports.

In some embodiments, each one of the plurality of internal filaments is electrically coupled to a plasma power/control system by a first contact and by a second contact.

In some embodiments, the plasma generation means comprises one or more external elements positioned around a chamber exterior.

In some embodiments, the plasma generation means comprises a pair of external electrodes positioned around the chamber exterior.

In some embodiments, the pair of external electrodes comprise an upper electrode positioned above the upper wall of the chamber body and a lower electrode positioned below the lower wall of the chamber body.

In some embodiments, the pair of external electrodes comprises a first lateral electrode positioned proximate to an exterior surface of the first side wall and a second lateral electrode positioned proximate to an exterior surface of the second side wall opposing the first side wall.

In some embodiments, the plasma generation means comprises one or more external coils extending around the chamber exterior between the injection flange and the substrate support.

In some embodiments, the plasma generation means comprises a first external coil extending laterally around the chamber exterior and longitudinally proximate to the injection flange and a second external coil extending laterally around the chamber exterior and extending longitudinally proximate to the substrate support.

In some embodiments, the injection flange further comprises a plurality of flow controllers configured to control a flow of the vapor phase process gas from a gas source assembly to the plurality of injection ports and therethrough to the chamber interior.

In some embodiments, the gas source assembly comprises a silicon precursor source in fluid communication with the injection flange and wherein the reactive species comprise one or more of silicon radicals, silicon metastables, and silicon ions.

In some embodiments, the chamber body has a plurality of external ribs extending laterally about a chamber exterior and longitudinally spaced apart from one another between the injection end and the longitudinally opposite exhaust end of the chamber body.

In some embodiments, the semiconductor processing system further comprising a heater element array supported around the chamber exterior and optically coupled to the substrate support, the heater element array comprising: a plurality of lower linear lamps supported below the chamber body and optically coupled to the substrate support by a quartz material forming the chamber body; and a plurality of upper linear lamps supported above the chamber body and optically coupled to the substrate support by the quartz material forming the chamber body.

In some embodiments, the semiconductor processing system further comprising a controller including a processor and a memory having instructions recorded on the memory that, when read by the processor, cause the processor to: seat the substrate on the substrate support; provide a controlled flow of the vapor phase process gas to the injection flange and therethrough to the chamber interior; and activate the plasma generation means to generate the reactive species from the vapor phase process gas at the plasma generation zone to deposit one or more epitaxial layers onto the substrate.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a cross-sectional view of a semiconductor processing system including a chamber arrangement in accordance with one or more embodiments.

FIG. 2 illustrates a plan view schematic of a chamber arrangement including plasma generation means in accordance with one or more embodiments.

FIG. 3 illustrates a cross-sectional view of a chamber arrangement including plasma generation means in accordance with one or more embodiments.

FIG. 4 illustrates a plan view schematic of a chamber arrangement including an internal filament in accordance with one or more embodiments.

FIG. 5 illustrates a cross-sectional view of a chamber arrangement including an internal filament in accordance with one or more embodiments.

FIG. 6 illustrates a cross-sectional view of a chamber arrangement including an internal filament and a filament support in accordance with one or more embodiments.

FIG. 7 illustrates an additional cross-sectional view of a chamber arrangement including an internal filament in accordance with one or more embodiments.

FIG. 8 illustrates a cross-sectional view of a chamber arrangement including a plurality of internal filaments in accordance with one or more embodiments.

FIG. 9 illustrates a plan view schematic of a chamber arrangement including a plurality of internal filaments in accordance with one or more embodiments.

FIG. 10 illustrates a cross-sectional view of a chamber arrangement including a pair of external electrodes in accordance with one or more embodiments.

FIG. 11 illustrates a plan view schematic of a chamber arrangement including a pair of external electrodes in accordance with one or more embodiments.

FIG. 12 illustrates a cross-sectional view of a chamber arrangement including a first external coil and a second external coil in accordance with one or more embodiments.

FIG. 13 illustrates a method for depositing an epitaxial layer on a substrate employing reactive species generated in a chamber interior in accordance with one or more embodiments

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Various embodiments provided relate to semiconductor processing systems, such as plasma enhanced chemical vapor deposition systems (PECVD) configured for the deposition of epitaxial layers on a substrate, as well as methods of depositing epitaxial layers employing the semiconductor processing systems. The semiconductor processing systems may be used to process substrates, such as semiconductor wafers. By way of examples, the systems described herein can be used to form or grow epitaxial layers (e.g., semiconductor layers) on a surface of a substrate.

Chemical vapor deposition (CVD) systems configured for the epitaxial deposition of semiconductor materials (such as epitaxial silicon layers) commonly deposit such layers by loading a substrate into a reaction chamber, heating the substrate to a desired deposition temperature, and exposing the substrate to a silicon precursor under environmental conditions selected to cause an epitaxial silicon layer to deposits on the substrate. The heating of the substrate is such that the silicon precursor decomposes into the epitaxial layer constituents, typically at a rate corresponding to the temperature of the substrate (i.e., the deposition temperature). While generally acceptable for its intended purpose, heating a substrate to a high deposition temperature (e.g., above 600° C., or for some precursors, above 1000° C.) consumes large amounts of power and consumables and may result in damage to the substrate and/or components of the semiconductor processing system employed in the deposition.

In the case of silicon epitaxy, the introduction of silicon reactive species generated by remote plasma sources located outside of the reaction chamber may be employed for reducing the deposition temperature. However, reactive species generated remotely tend to recombine prior to contacting the substrate thereby limiting the effectiveness of common remote plasma generation techniques for epitaxial deposition processes.

Various embodiments provide semiconductor processing system configured for the epitaxial deposition of semiconductor layers at a reduced deposition temperature. The various embodiments employ plasma generation means configured for generating reactive species (e.g., ions, radicals, metastable, and the like) within the interior of the PECVD reaction chamber. Generating the reactive species within the interior of the reaction chamber, and particular in the vicinity of the substrate upon which deposition occurs, can reduce the recombination of the radical species, thereby increasing the efficiency of the deposition system.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

The terms precursor gas and/or precursor gasses may refer to a gas or combination of gasses that participate in a chemical reaction that produces another compound. For example, precursor gasses may be used to grow an epitaxial layer comprising silicon germanium. Precursor gasses may include a deposition gas or gasses, a dopant gas or gasses, or a combination of a deposition gas or gasses and a dopant gas or gasses. The precursor gases may include a silicon precursor such as a high-order silicon precursor. The silicon precursor may further include silane (SiH₄) or chlorosilane (SiCl₄). In some examples, the high-order silicon precursor may have one silicon atom per molecules, such as silane. The high-order silicon precursor may have two or more silicon atoms per molecules, such as disilane. In some examples, the high-order silicon precursors may have three or more silicon atoms. The high-order silicon precursors may include a non-halogenated high-order silicon precursor, such as trisilane and tetrasilane. The high-order silicon precursor may include a halogenated high-order silicon precursor, for example, a high-order chlorine-containing precursors, such as chlorodisilane, dichlorosilane, trichlorosilane, and tetrachloridesilane. The precursor gases may include a high-order germanium-containing material layer precursor, such as germane, digermane, trigermane, their chloride derivatives and mixtures thereof. The precursor gases may include a P-dopant high order precursor such as diborane (B₂H₆). The precursor gases may also include an N-dopant high order precursor such as phosphine (PH₃) and arsine (AsH₃).

As used herein, the term “epitaxial layer” can refer to a single crystalline layer (or substantially single crystalline layer) directly on an underlying single crystalline (or substantially single crystalline) substrate or layer.

As used herein, the term “chemical vapor deposition” or “CVD” can refer to any process wherein a substrate is exposed to one or more volatile precursors (as well as optional additional process gases), which react and/or decompose on a substrate surface to produce a desired deposition.

In the following description of the various embodiments, reference is made to the accompanying drawings, which form a part hereof, and in which is shown by way of illustration various embodiments in which aspects of the disclosure may be practiced. It is to be understood that other embodiments may be utilized, and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

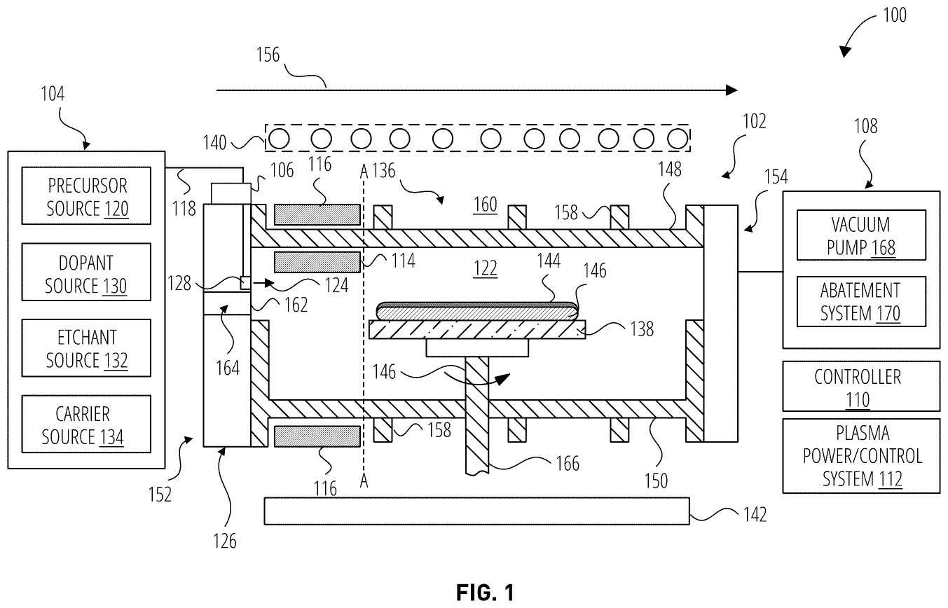

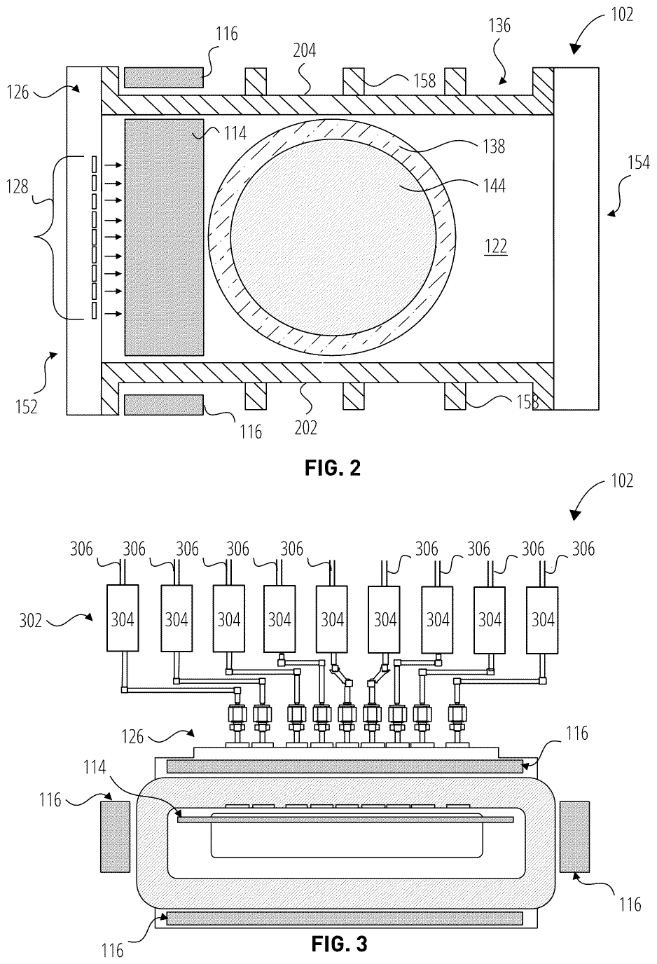

In accordance with examples of the disclosure, FIG. 1 illustrates a cross-sectional view of a semiconductor processing system 100 including a chamber arrangement 102. FIG. 2 illustrates a plan view schematic of the chamber arrangement 102 and FIG. 3 illustrates a cross-sectional view of a portion of the chamber arrangement 102 through the A-A plane illustrated in FIG. 1.

In various embodiments, the semiconductor processing system 100 includes a chamber arrangement 102. The chamber arrangement 102 is supplied with a vapor phase process gas from a gas source assembly 104 in conjunction with an optional gas distribution assembly 106. The semiconductor processing system 100 also includes an exhaust assembly 108, a controller 110, and a plasma power/control system 112. Although illustrated in FIG. 1 as a separate controller 110 and plasma power/control system 112, both systems may be combined into a single control system configured for providing the operations and functionality of both the controller 110 and the plasma power/control system 112. In addition, the semiconductor processing system 100 includes plasma generation means (114, 116) configured to generating reactive species (e.g., from a plasma) within the interior of the chamber, as is described in detail below.

The gas source assembly 104 is constructed and arrange to provide a vapor phase process gas to the chamber arrangement 102. The vapor phase process gas can comprise a singular gas or a mix of gases including, but not limited to, precursor gases, dopant gases, etchant gases, and inert gases (e.g., purge gases, carrier gases). The gas source assembly 104 can include various systems, sub-systems, and components (not illustrated) for generating and controlling the flow of the vapor phase process gas, from the sources included therein, to the process gas supply line 118 which fluidly connects the gas source assembly 104 to the chamber arrangement 102 via the gas distribution assembly 106. The gas source assembly 104 includes a precursor source 120 which can include a number of precursor sources. In some embodiments the precursor source 120 comprises a silicon source including one or more silicon precursors. The vapor phase process gas provided by the gas source assembly 104 is introduced into the chamber interior 122 (e.g., as indicated by process gas flow 124) through an injection flange 126 including a plurality of injection ports 128, as described in detail below.

In various embodiments, the precursor source 120 sub-system of the gas source assembly 104 includes a silicon source (not illustrated). The silicon source can comprise a sub-system that provides a flow of a silicon precursor to the chamber arrangement 102 through the injection flange 126 and therethrough to the plurality of injection ports 128 and into the chamber interior 122, as indicated by process gas flow 124 in FIG. 1.

In some embodiments the silicon source includes a silicon precursor having one silicon atom per molecule such as silane (SiH₄) or monochlorosilane (ClH₃Si). Alternatively (or additionally), the silicon precursor can include a high-order silicon precursor such as a silicon precursor having two or more silicon atoms per molecule, or three or more silicon atoms in certain examples. The high-order silicon precursors may include a non-halogenated high-order silicon precursor, such as trisilane and tetrasilane. The high-order silicon precursor may include a halogenated high-order silicon precursor, for example, a high-order chlorine-containing precursors, such as chlorodisilane, dichlorosilane, trichlorosilane, and tetrachloridesilane.

In some embodiments the silicon source includes a silane and/or a halosilane. In some embodiments, the silicon precursor can include a hydrogenated silicon precursor. In such embodiments the hydrogenated silicon precursor can be selected from a group consisting of silane (SiH₄), disilane (Si₂H₆), trisilane (Si₃H₈), and tetrasilane (Si₄H₁₀). In further embodiments the silicon precursor can comprise a silicon halide precursor. In such examples the silicon halide precursor can comprise a silicon chloride precursor selected from a group consisting of monochlorosilane (MCS), dichlorosilane (DCS), trichlorosilane (TCS), hexachlorodisilane (HCDS), octachlorotrisilane (OCTS), and silicon tetrachloride (STC). In further embodiments the silicon precursor can comprise a silicon iodide precursor. In such examples the silicon halide precursor can comprise a silicon iodide precursor selected from a group consisting of monoiodosilane, diiodosilane, triiodosilane, tetraiodosilane.

The precursor source 120 sub-system of the gas source assembly 104 can include a germanium source (not illustrated). The germanium source may provide a flow of a germanium precursor to the chamber arrangement 102 through the injection flange 126 including the plurality of injection ports 128.

The germanium source can include a germanium precursor such as a germane and/or a germanium halide. For example, the germanium precursor may comprise a germane, such as germane (GeH₄), digermane (Ge₂H₆), trigermane (Ge₃H₈), or germylsilane (GeH₆Si). In further examples, the germanium precursor may comprise a germanium halide such as GeCl₄, GeCl₂, and GeCl₂H₂.

In addition to the precursor source 120, the gas source assembly 104 can include a dopant source 130, an etchant source 132, and a carrier source 134. The dopant source 130 can include dopant compounds such as phosphorous (P), boron (B) and/or arsenic (As). In some examples the dopant source can include a p-dopant such as borane, diborane (B₂H₆), deuterium-diborane (B₂D₆), and boron halides such as BBr₃, BH₂Cl and BCl₂H. In other examples, the dopant source 130 can include an n-dopant such as phosphine (PH₃) and arsine (AsH₃). The etchant source 132 can include a halide-containing compound. The halide-containing compound can be flowed independently from the precursor, such as to provide a purge and/or to remove condensate from within the chamber arrangement 102. The halide-containing compound can be co-flowed with one or more other process gases. Examples of suitable halides include chlorine (Cl), e.g., chlorine (Cl₂) gas and hydrochloric (HCl) acid, as well as fluorine (F), e.g., fluorine (F₂) gas and hydrofluoric (HF) acid. The carrier source 134 can be configured to provide an inert carrier gas and/or a purge gas to the chamber arrangement 102. Examples of suitable purge/carrier gases may include hydrogen (H₂) gas, nitrogen (N₂) gas, inert gases such as argon (Ar) gas or helium (He) gas, and mixtures thereof.

In accordance with examples of the disclosure, the semiconductor processing system 100 includes the chamber arrangement 102. The chamber arrangement 102 can comprise a cross flow, cold wall epitaxial reaction chamber. The chamber arrangement 102 may include a chamber body 136 and a substrate support 138. The chamber arrangement 102 may include an upper heater element array 140 and a lower heater element array 142, as illustrated in FIG. 1. Although a specific arrangement is shown and described herein, it is to be understood and appreciated that the chamber arrangement 102 may include other elements and/or omit elements shown and described herein and remain within the scope of the present disclosure.

In accordance with examples of the disclosure and with reference to FIG. 1 FIG. 2 and FIG. 3, the chamber arrangement 102 includes a chamber body 136. The chamber body 136 includes an upper wall 148, and a lower wall 150, a first side wall 202 (FIG. 2) and a second side wall 204 opposing the first side wall 202. The upper wall 148 and the lower wall 150 extend longitudinally between an injection end 152 and a longitudinally opposite exhaust end 154, at least partially defining a chamber interior 122 and a chamber exterior 160. As used herein the longitudinal orientation of the chamber body 136 (and the relative orientation and location of elements of the chamber arrangement 102) can be indicated by the longitudinal axis 156. The lower wall 150 is below and parallel to the upper wall 148. In certain examples, the chamber body 136 may be formed from a ceramic material such as sapphire or quartz. The chamber body 136 may include a plurality of external ribs 158. The plurality of external ribs 158 may extend laterally about the chamber exterior 160 and be longitudinally spaced between the injection end 152 and the exhaust end 154 of the chamber body 136. It is also contemplated that, in accordance with certain examples, the chamber body 136 may include no ribs.

In accordance with examples of the disclosure, the chamber arrangement 102 (FIG. 1) includes an injection flange 126 coupled to the injection end 152 of the chamber body 136. The injection flange 126 includes a front face 162 which is coupled with the injection end 152 of the chamber body 136. The injection flange 126 can include a substrate channel 164 through which a substrate (such as substrate 146) can be loaded and unloaded to and from the chamber interior 122. The injection flange 126 includes a plurality of injection ports 128 (as illustrated by an exemplary injection port 128 in FIG. 1 and by the series of injection ports 128 in FIG. 2 and FIG. 3). In some examples, the plurality of injection ports 128 are disposed in a front face 162 of the injection flange 126. In other examples, the plurality of injection ports 128 are proximate to the front face 162 of the injection flange 126, for example, the plurality of injection ports 128 can be disposed in the upper surface of the substrate channel 164.

In various embodiments the injection flange 126 comprises a gas distribution assembly 106 including plurality of flow controllers 304 (as illustrated in FIG. 3) which can be configured to control a flow of the vapor phase process gas from the gas source assembly 104 to the plurality of injection ports 128 and therethrough to the chamber interior 122.

In accordance with examples of the disclosure, the gas distribution assembly 106 (as illustrated in FIG. 3) comprising one or more (e.g., a plurality) of gas lines 306 which can be coupled to the gas source assembly 104 (FIG. 1). In various embodiments, each one of the plurality of gas lines 306 can be coupled to a corresponding flow controller 304. The flow controllers 304 allow independent control of a flow (e.g., a flow rate) of respective gases to the injection ports 128 of the injection flange 126 and therethrough to the chamber interior 122. The flow controllers 304 can include any suitable automatic or manual valve that can control a flow rate of gas to a respective gas channel disposed within the injection flange 126. Although the injection flange 126 is illustrated in FIG. 3 as including nine (9) gas line 306, with nine (9) corresponding flow controllers 304, and nine (9) injection ports, the injection flange 126 can include any suitable number of injection ports (and associated gas lines and flow controllers). In some embodiments the injection flange 126 can comprise between 1 and 10 injection ports fed from between 1 and 10 gas lines (via corresponding flow controllers). In some embodiments the injection flange 126 can comprise less than 10 injections ports and correspond gas lines and flow controllers, less than 8 injection ports and corresponding gas lines and flow controllers, less than 5 injection ports and corresponding gas lines and flow controllers, or less than 3 injection ports and corresponding gas lines and flow controllers.

As illustrated in FIG. 1 and FIG. 2, a substrate support 138 is disposed within the chamber interior 122. The substrate support 138 can be positioned between the injection end 152 and the exhaust end 154 of the chamber body 136. The substrate support 138 includes a shaft member 166 arranged within the chamber body 136 and configured for rotation about a rotation axis within the chamber interior 122. The substrate support 138 can be formed from an opaque material, such as silicon carbide or a bulk graphite material.

The upper heater element array 140 can be configured to heat a substrate 146 and/or an epitaxial layer 144 during deposition on the substrate 146 by radiantly communicating heat into the chamber interior 122. The upper heater element array 140 can include a plurality of upper linear lamps supported above the chamber body 136 (e.g., above the upper wall 148) and optically coupled to the substrate support 138 by the material forming the chamber body, e.g., a quartz material. The lower heater element array 142 can be similar to the upper heater element array 140 and can also be configured to heat the substrate 146 and/or the epitaxial layer 144 during deposition on the substrate 146. The lower heater element array 142 can include a plurality of lower linear lamps supported below the chamber body 136 (e.g., below the lower wall 150) and optically coupled to the substrate support 138 by the material forming the chamber body 136. In various embodiments the upper heater element array 140 and/or the lower heater element array 142 may be employed in conjunction with the various plasma generation means (114, 116) for epitaxially depositing an epitaxial layer 144 on the substrate 146.

The semiconductor processing system 100 includes an exhaust assembly 108. The exhaust assembly 108 can be configured to evacuate the chamber arrangement 102 and can include one or more vacuum pumps 168 and an abatement system 170. The vacuum pumps 168 can be connected to the chamber arrangement 102 and configured to control the pressure within the chamber interior 122. The abatement system 170 can be connected to the one or more vacuum pumps 168 and be configured to process the flow of residual precursor and/or reaction products issued from the chamber arrangement 102. In some embodiments, the exhaust assembly 108 may be configured to maintain environmental conditions within the chamber interior 122 suitable for deposition operations. In one example the exhaust assembly 108 is configured to maintain environmental conditions within the chamber interior 122 suitable for extending the lifetimes of the reactive species generated by the plasma generation means (e.g., 114, 116).

The semiconductor processing system 100 further comprise a controller 110 including a processor and memory having instructions recorded on the memory that, when read by the processor, cause the processor to perform processes for depositing an epitaxial layer 144 on the substrate 146, as described in detail below.

The semiconductor processing system 100 can include a plasma power/control system 112. In some embodiments, the plasma power/control system 112 may be employed in addition to the controller 110. In some embodiments, a single controller (e.g., 110 or 112) can be employed for operating the various systems/sub-systems of semiconductor processing system 100 (FIG. 1) as well as the powering and controlling the generation of reactive species in the chamber interior employing the plasma generation means (114 and/or 116).

In accordance with examples of the disclosure, the plasma power/control system 112 can include various system and sub-systems for generating and controlling a plasma including, for example, a power supply and a matching network. The power supply can be selected from a DC power supply, an AC power supply, a RF power supply, a microwave power generator, and the like. Plasma power/control system 112 can include a matching network. For example, a matching network can be employed for adjusting the impedance between the power supply and the plasma load to ensure efficient power transfer and stable plasma conditions in the chamber interior 122. In addition, the plasma power/control system 112 can include various sensors and monitoring systems to assess the plasma state and/or the generation of reactive species within the chamber interior 122.

In accordance with examples of the disclosure, semiconductor processing system 100 and particularly the chamber arrangement 102 (as illustrated in FIG. 1, FIG. 2, and FIG. 3) includes plasma generation means configured for generating a reactive species from the vapor process gas supplied from the gas distribution assembly 106 via the optional gas distribution assembly 106. In such examples, the reactive species can be generated within the chamber interior 122 at a plasma generation zone disposed between the injection flange 126 and the substrate support 138.

In various embodiments, the plasma generation means includes one or more internal elements disposed within the chamber interior 122. For example, FIG. 1, FIG. 2, and FIG. 3 illustrates the internal elements 114 configured for generating a reactive species (e.g., from a plasma) within the chamber interior 122, as described in detail below.

In various embodiments, the plasma generation means includes one or more external elements disposed around the chamber exterior 160. For example, FIG. 1, FIG. 2, and FIG. 3 illustrates the external element 116 configured for generating a reactive species (e.g., from a plasma) within the chamber interior 122, as described in detail below.

In accordance with examples of the disclosure, the plasma generation means may comprise one or more internal filaments disposed within the chamber interior. In such examples, the internal filament(s) can be positioned between the injection flange and the substrate support.

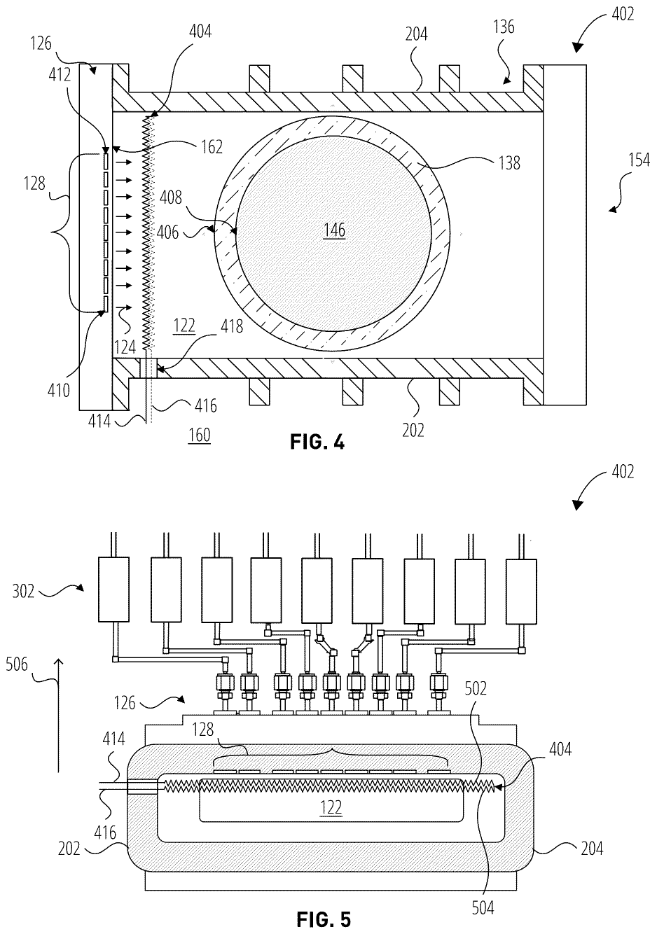

FIG. 4 illustrates a plan view schematic of a chamber arrangement 402 including an internal filament 404 configured for generating a reactive species in the chamber interior 122.

In various embodiments, the internal filament 404 is positioned between the injection flange 126 and the substrate support 138. In one example, the internal filament 404 is positioned longitudinally (i.e., along the longitudinal axis 156 of FIG. 1) between the front face 162 of the injection flange 126 and an outer perimeter 406 of the substrate support 138. In another example, the internal filament 404 is positioned longitudinally between the front face 162 of the injection flange 126 and an outer perimeter 408 of the substrate 146.

In accordance with examples of the disclosure, the internal filament 404 can be longitudinally proximate to the plurality of injection port 128. In some embodiments the internal filament 404 is positioned adjacent to the plurality of injections injection ports 128. For example, the internal filament 404 can be positioned proximate to the plurality of injection ports such that the internal filament 404 intersects a flow path (as indicated by process gas flow 124 in FIG. 4) of the vapor phase process gas into the chamber interior 122.

In accordance with examples of the disclosure, the internal filament 404 can extend perpendicular (to the longitudinal axis 156) between the first side wall 202 and second side wall 204 opposing the first side wall 202. In such examples, the internal filament 404 can be orientated parallel to the front face 162 of the injection flange 126, as illustrated in FIG. 4. In some embodiments the internal filament 404 extends perpendicularly into the chamber interior 122 between a first injection port 410 (of the plurality 128) and a last injection port 412 (of the plurality 128). In such embodiments the internal filament 404 extends perpendicularly across the entire extent of the process gas flow 124 introduced into the chamber interior 122 through the plurality of injection ports 128. In such embodiments the internal filament 404 extends perpendicularly across the entire diameter of the substrate 146 disposed on the substrate support 138.

In accordance with examples of the disclosure, the internal filament 404 is electrically coupled to an exterior plasma power/control system (e.g., such as 112 of FIG. 1). In such examples the internal filament 404 includes a first filament contact 414 and a second filament contact 416. In some examples, the first filament contact 414 and the second filament contact 416 can both extend through the first side wall 202 (from the chamber interior 122 to the chamber exterior 160) and therethrough to the plasma power/control system 112 (FIG. 1). In such examples the first side wall 202 can include a feedthrough aperture 418 which extends through the first side wall 202 from the chamber interior 122 to the chamber exterior 160. The feedthrough aperture 418 can comprise an aperture formed through the full thickness of the first side wall 202 to allow electrical connection between the plasma power/control system 112 and the internal filament 404. In addition, the feedthrough aperture 418 can be constructed and arranged to seal the chamber interior 122 from the chamber exterior 160 to allow the chamber body to be placed under vacuum. In addition, the feedthrough aperture 418 can be constructed and arranged to prevent electrical shorting between the contacts (414, 416) to the internal filament 404. In addition, the feedthrough aperture 418 can provide a support assembly to the internal filament 404 within the chamber interior 122 thereby maintaining the optimum position of the internal filament 404 in relation to internal elements within the chamber interior 122. In such examples, the internal filament 404 can be supported in a cantilever configuration, as described below.

FIG. 5 illustrates a cross-sectional view of the chamber arrangement 402 (of FIG. 4) through the A-A plane (as illustrated in FIG. 1).

In various embodiments the internal filament 404 is supported in the chamber interior 122 between the injection flange 126 and the substrate support 138 by a cantilever configuration. In such embodiments the internal filament 404 is supported at the first side wall 202 and not support at the second side wall 204 (or vice versa) in a cantilever configuration, as illustrated in FIG. 5.

In accordance with examples of the disclosure, the internal filament 404 can include a single continuous (e.g., electrical/physically) filament. In some embodiments the internal filament 404 comprises an upper filament section 502 and a lower filament section 504 (FIG. 5). In some embodiments the upper filament section 502 and lower filament section 504 are proximate or adjacent to one another, whilst maintaining sufficient distance between to the two filament sections to prevent an electrical short between the two filament sections (502 and 504).

In various embodiments the internal filament 404 is vertically positioned within the chamber interior 122 (i.e., along vertical chamber axis 506) such that the internal filament 404 is proximate to the plurality of injection ports 128 (as illustrated in FIG. 5). In some embodiments the internal filament 404 is vertically positioned within the chamber interior 122 adjacent to the plurality of injection ports 128. In some embodiments the internal filament 404 is vertically proximate to the plurality of injection ports 128 such that the internal filament 404 intersects a flow path of the vapor phase process gas into the chamber interior 122.

FIG. 6 illustrates a cross-sectional view of a chamber arrangement 602 through the A-A plane (as illustrated in FIG. 1). The chamber arrangement 602 can be alike the chamber arrangement 402 of FIG. 4 and FIG. 5 except in the configuration of the internal filament within the chamber interior.

In accordance with examples of the disclosure, chamber arrangement 602 includes an internal filament 604. Internal filament 604 can be positioned (both longitudinally and vertically) as previously described. In some embodiments the internal filament 604 includes an upper filament section 606 and a lower filament section 608, as described above.

In accordance with examples of the disclosure, the internal filament 604 can include a first end 610 supported at the first side wall 202 and a second end 612 supported at the second side wall 204. In such examples, the internal filament 604 is supported at both the lateral side walls (202 and 204) of the chamber body 136.

In some embodiments, the first end 610 of the internal filament 604 can be supported at the first side wall 202 by an assembly comprising a first filament contact 616, a second filament contact 618, and a feedthrough aperture 620 (as described above). In some embodiments chamber arrangement 602 can include a filament support 614 configured to support the second end 612 of the internal filament 604 at the second side wall 204. In some examples, the filament support 614 is disposed within the chamber interior 122. In some embodiments, the filament support 614 comprises an insulating material, such as, for example, quartz, and/or silicon carbide. In various examples the filament support 614 is constructed from quartz. In some examples the filament support 614 can be an integral element of the chamber body 136.

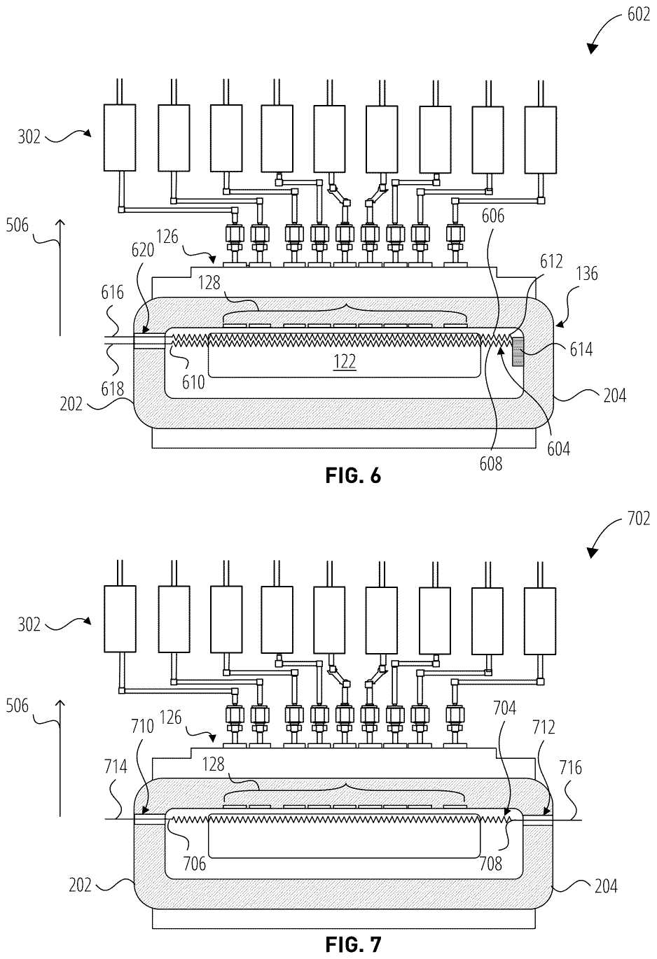

FIG. 7 illustrates a cross-sectional view of a chamber arrangement 702 through the A-A plane (as illustrated in FIG. 1). The chamber arrangement 702 can be alike the chamber arrangements 402 and 602 except in the configuration of the internal filament within the chamber interior.

In accordance with examples of the disclosure, chamber arrangement 702 includes an internal filament 704. Internal filament 704 can be positioned (both longitudinally and vertically) as previously described with reference to internal filament 404 and internal filament 604.

In various embodiments, the internal filament 704 can include a first end 706 supported at the first side wall 202 and a second end 708 supported at the second side wall 204. For example, the internal filament 704 can be supported at both the lateral side walls (202 and 204) of the chamber body 136. In chamber arrangement 702, the first end 706 of the internal filament 704 can be supported at the first side wall 202 by an assembly comprising a first filament contact 714 and a first feedthrough aperture 710 and the second end 708 of the internal filament 704 can be supported at the second side wall 204 by an assembly comprising a second filament contact 716 and a second feedthrough aperture 712. In such examples the internal filament 704 is electrically coupled to an exterior plasma power/control system (such as plasma power/control system 112 of FIG. 1) by the first filament contact 714 extending through the first side wall 202 and by the second filament contact 716 extending through the second side wall 204 opposing the first side wall 202.

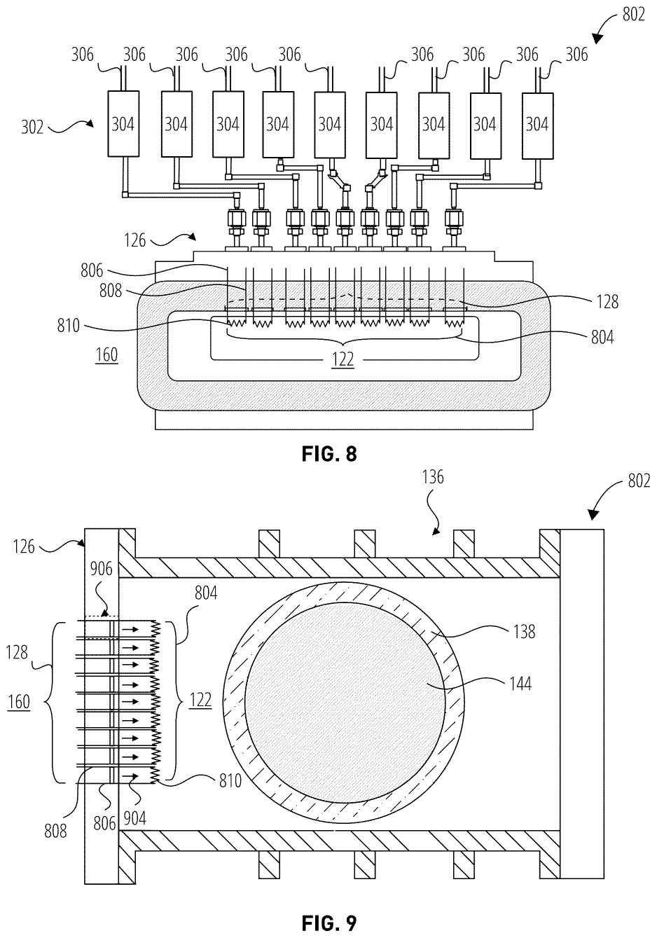

FIG. 8 and FIG. 9 illustrate a chamber arrangement 802. For example, FIG. 8 illustrates a cross-sectional view of the chamber arrangement 802 through the A-A plane (as illustrated in FIG. 1) and FIG. 9 illustrates a plan view schematic of the chamber arrangement 802. The chamber arrangement 802 can be alike the chamber arrangements 402, 602 and 702 except in the configuration of the internal filament within the chamber interior.

In accordance with examples of the disclosure, chamber arrangement 802 comprises a plurality of internal filaments 804. In such examples each one of the plurality of internal filaments 804 is positioned proximate to one of the plurality of injection ports 128 such that each one of the plurality of internal filaments 804 intersects an individual flow path 904 of the vapor phase process gas introduced by one of the plurality of injection ports 128. In such examples, each one of the plurality of internal filaments 804 can be longitudinally and vertically positioned within the chamber interior 122 to be proximate and/or adjacent to one of the injection ports of the plurality of injection ports 128.

The plurality of internal filaments 804 can be individual electrically contacted and controlled by the plasma power/control system 112 (FIG. 1). In some embodiments each one of the internal filaments of the plurality of internal filaments includes a first contact and a second contact which are routed from the chamber interior 122 to the chamber exterior 160 and thereon to the plasma power/control system 112. For example, FIG. 8 and FIG. 9 illustrate an exemplary single internal filament 810 (of the plurality of internal filaments 804) which comprises a first contact 806 and a second contact 808. Each of the single internal filaments (e.g., 810) making up the plurality of internal filaments 804 can each include a first contact and a second contact.

In some embodiments each of the first contacts and the second contacts, electrically connecting the plurality of internal filaments 804 to the plasma power/control system 112, can be routed to the chamber exterior 160 through the injection flange 126. In one example a series of feedthroughs can disposed through the injection flange 126 from the chamber interior 122 (e.g., through the front face 162 of the injection flange 126) to the chamber exterior 160 and therethrough the plasma power/control system 112 as illustrated in FIG. 9 by exemplary flange feedthrough 906. In some embodiments the injection flange 126 comprises a single flange feedthrough through which all the first contacts and the second contacts are routed from the chamber interior 122 to the chamber exterior 160 (not illustrated).

In some embodiments each of the first contacts and the second contacts, electrically connecting the plurality of internal filaments 804 to the plasma power/control system 112, can be routed to the chamber exterior 160 through one or more feedthrough aperture disposed in the walls of the chamber body 136. In such examples, the feedthrough apertures can comprise the first feedthrough aperture 710 and/or the second feedthrough aperture 712 as illustrated in FIG. 7.

As illustrated in FIG. 8 and previously described above with reference to FIG. 3, the chamber arrangement 802 can include a gas distribution assembly 302. The gas distribution assembly 302 can be configured to control the flow rate of the vapor phase process gas through each of the individual injection ports by use of the plurality of gas lines 306 and their associated flow controller 304. In some examples, the gas distribution assembly 302 in conjunction with the individually controllable plurality of internal filaments 804 can provide a means to vary the properties of the plasma and hence the generation of the reactive species perpendicularly across the width of the chamber interior 122 (i.e., perpendicular to the longitudinal axis 156) and hence across the substrate 146 disposed within the chamber interior. In such examples the uniformity of the epitaxial layer 144 deposited on the substrate 146 may be controlled and/or improved. In some embodiments the individual flows to the each of the plurality of injections ports is controlled with the gas distribution assembly 302 to control the uniformity of the epitaxial layer 144 deposited on the substrate 146. In some embodiments each of the internal filaments of the plurality of internal filaments 804 is controlled with the plasma power/control system 112 to control the uniformity of the epitaxial layer 144 deposited on the substrate 146. In some embodiments the uniformity of the epitaxial layer 144 deposited on the substrate 146 can be controlled by both the gas distribution assembly 302 and the plasma power/control system 112.

In accordance with examples of the disclosure, the plasma generation means for generating the reactive species in the chamber interior may comprise one or more external elements. In some embodiments, the one or more external elements can be positioned around the chamber exterior. In such examples, the external elements can be disposed around the chamber exterior and can be supported by the chamber body between the injection flange and the substrate support.

In various embodiments the external elements for generating reactive species in the chamber interior can comprises a pair of external electrodes.

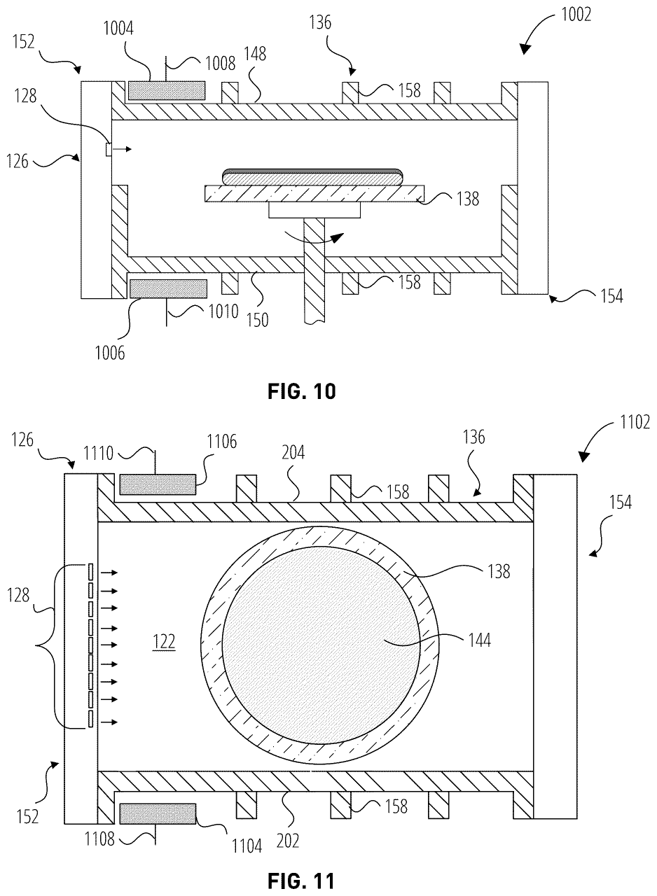

FIG. 10 illustrates a cross-sectional view of a chamber arrangement 1002 comprising a pair of electrodes. In various embodiments the pair of external electrodes comprises an upper electrode 1004 positioned above the upper wall 148 of the chamber body 136 and a lower electrode 1006 positioned below the lower wall 150 of the chamber body 136. In such embodiments the upper electrode 1004 and the lower electrode are positioned longitudinally between the injection flange 126 and the substrate support 138. In some embodiments the upper electrode 1004 and the lower electrode 1006 are longitudinally proximate or adjacent to the plurality of injection port (as illustrated by exemplary injection port 128 in FIG. 10). In such examples, the upper electrode 1004 comprise an upper electrode contact 1008 and the lower electrode 1006 comprises a lower electrode contact 1010 for connecting the upper and lower electrodes to the plasma power/control system 112.

FIG. 11 illustrates cross-sectional view of a chamber arrangement 1102 comprising a pair of external electrodes. In various embodiments the pair of external electrodes can comprise a first lateral electrode 1104 positioned proximate to an exterior surface of the first side wall 202 and a second lateral electrode 1106 positioned proximate to an exterior surface of the second side wall 204 opposing the first side wall 202.

In some embodiments the first lateral electrode 1104 and the second lateral electrode 1106 are positioned longitudinally between the injection flange 126 and the substrate support 138. In some embodiments the first lateral electrode 1104 and the second lateral electrode 1106 are longitudinally proximate or adjacent to the plurality of injection port 128. In such examples, the first lateral electrode 1104 comprise a first lateral electrode contact 1108 and the second lateral electrode 1106 comprises a second lateral electrode contact 1110 for connecting the first and second lateral electrode to the plasma power/control system 112.

In various embodiments the external elements for generating reactive species in the chamber interior can comprises one or more external coils. In such embodiments the one or more external coils can extend around the chamber exterior between the injection flange and substrate support.

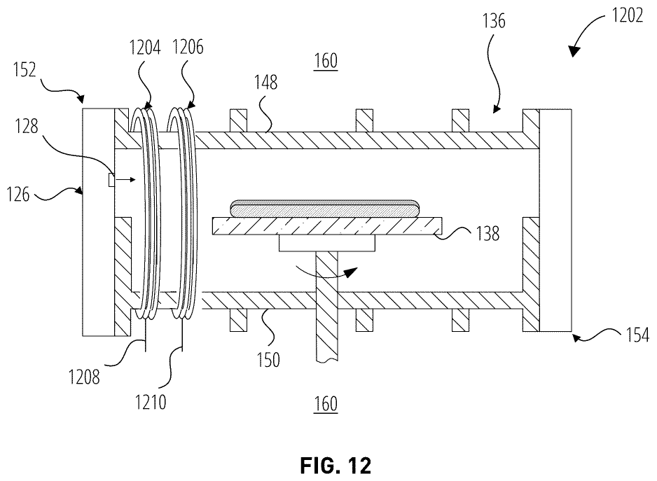

FIG. 12 illustrates a cross-sectional view of a chamber arrangement 1202 in accordance with embodiments of the disclosure. In various embodiments chamber arrangement 1202 comprises a first external coil 1204 extending laterally around the chamber exterior 160 and longitudinally proximate to the injection flange 126 and a second external coil 1206 extending laterally around the chamber exterior 160 and extending longitudinally proximate to the substrate support 138. In some embodiments the first external coil 1204 is connected to the plasma power/control system 112 by the first coil contact 1208 and the second external coil 1206 is connected to the plasma power/control system 112 by the second coil contact 1210. In some embodiments the first external coil 1204 can be positively biased and the second external coil 1206 can be negatively biased.

The various embodiments provided may include a semiconductor processing system 100 comprising a controller 110 (which can also incorporate the plasma power/control system 112) communicatively coupled with various other components of the semiconductor processing systems 100, as illustrated in FIG. 1 (including the associated chamber arrangements illustrated in FIG. 2-FIG. 12) and may be configured to control their operations. For example, the controller 110 may control the plasma generation means (e.g., internal elements 114 and/or external element 116), such as by controlling one or more of the plasma power and ignition. The controller 110 may control the flow of the vapor phase process gas into the chamber interior 122 from the injection flange. The controller 110 may control the flow of the reactive species generated in the chamber interior over the substrate support 138. The controller 110 may control the seating of the substrate 146 on the substrate support 138, heating of the substrate (e.g., employing upper heater element array 140 and/or lower heater element array 142), and/or flow of one or more gases provided by the gas source assembly, and in addition control the gas distribution assembly 302 to the injection flange 126.

In various embodiments the controller including a processor and a memory having instructions recorded on the memory that, when read by the processor, cause the processor to: seat the substrate on the substrate support; provide a controlled flow of the vapor phase process gas to the injection flange and therethrough to the chamber interior; and activates the plasma generation means to generate the reactive species from the vapor phase process gas within the chamber interior between the injection flange and the substrate support at a plasma generation zone to deposit one or more epitaxial layers onto the substrate.

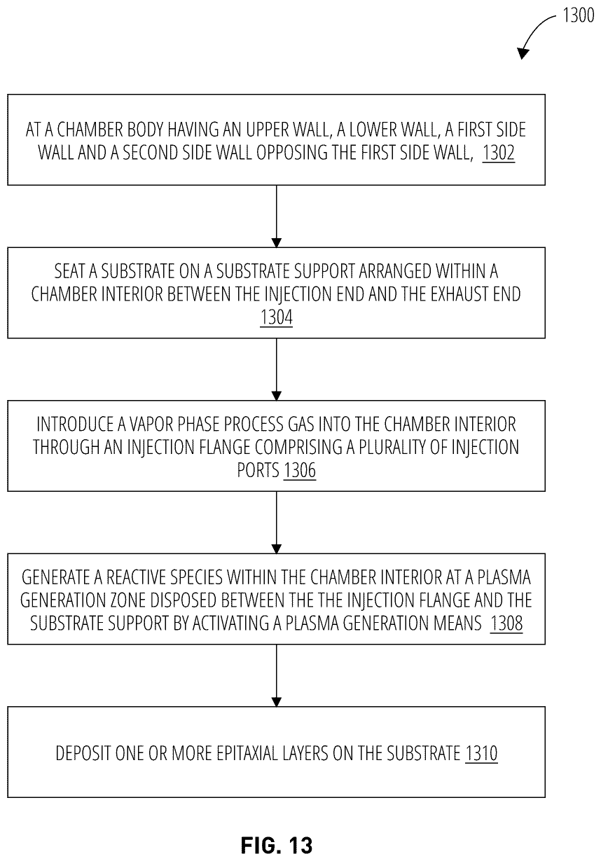

Various embodiments provided include methods for depositing epitaxial layers employing the semiconductor processing systems and chamber arrangements previously described. FIG. 13 illustrates a method 1300 for depositing an epitaxial layer on a substrate by a plasma assisted chemical vapor deposition process, the method comprising: at a chamber body having an upper wall, a lower wall, a first side wall and a second side wall opposing the first side wall, wherein the upper wall extends longitudinally between an injection end and a longitudinally opposite exhaust end, and the lower wall is below and parallel relative to the upper wall (step 1302); seating the substrate on a substrate support arranged within a chamber interior between the injection end and the exhaust end (step 1304); introducing a vapor phase process gas into the chamber interior through an injection flange comprising a plurality of injection ports, the injection flange coupled to the injection end of the chamber body (step 1306); generating a reactive species within the chamber interior at a plasma generation zone disposed between the injection flange and the substrate support (step 1308); and depositing one or more epitaxial layers on the substrate (step 1310).

In some embodiments method 1300 further comprises heating the substrate to a deposition temperature employing a heater element array supported around a chamber exterior and optically coupled to the substrate support, the heater element array comprising: a plurality of lower linear lamps supported below the chamber body and optically coupled to the substrate support by a quartz material forming the chamber body; and a plurality of upper linear lamps supported above the chamber body and optically coupled to the substrate support by the quartz material forming the chamber body.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing system configured for performing plasma enhanced epitaxial deposition processes, the semiconductor processing system comprising:
a chamber body having an upper wall, a lower wall, a first side wall and a second side wall opposing the first side wall, wherein the upper wall extends longitudinally between an injection end and a longitudinally opposite exhaust end, and the lower wall is below and parallel relative to the upper wall;
a substrate support configured to support a substrate and arranged within a chamber interior between the injection end and the exhaust end;
an injection flange comprising a plurality of injection ports coupled to the injection end and configured for introducing a vapor phase process gas into the chamber interior; and
a plasma generation means configured for generating a reactive species from the vapor phase process gas within the chamber interior at a plasma generation zone disposed between the injection flange and the substrate support.

2. The semiconductor processing system of claim 1, wherein the plasma generation means comprises one or more internal elements disposed within the chamber interior.

3. The semiconductor processing system of claim 2, wherein the plasma generation means comprises an internal filament longitudinally positioned between the injection flange and the substrate support.

4. The semiconductor processing system of claim 3, wherein the internal filament is positioned proximate to the plurality of injection ports such that the internal filament intersects a flow path of the vapor phase process gas into the chamber interior.

5. The semiconductor processing system of claim 4, wherein the internal filament extends perpendicular between the first side wall and the second side wall opposing to the first side wall.

6. The semiconductor processing system of claim 5, wherein the internal filament is electrically coupled to an exterior plasma power/control system by a first contact and a second contact both extending through the first side wall from the chamber interior to a chamber exterior.

7. The semiconductor processing system of claim 6, wherein the internal filament is supported at the first side wall by a cantilever configuration.

8. The semiconductor processing system of claim 5, wherein the internal filament is electrically coupled to a plasma power/control system by a first contact extending through the first side wall and by a second contact extending through the second side wall opposing the first side wall.

9. The semiconductor processing system of claim 3, wherein the internal filament is one of a plurality of internal filaments and each one of the plurality of internal filaments is positioned proximate to one of the plurality of injection ports such that each one of the plurality of internal filaments intersects an individual flow path of the vapor phase process gas introduced by one of the plurality of injection ports.

10. The semiconductor processing system of claim 9, wherein each one of the plurality of internal filaments is electrically coupled to a plasma power/control system by a first contact and by a second contact.

11. The semiconductor processing system of claim 1, wherein the plasma generation means comprises one or more external elements positioned around a chamber exterior.

12. The semiconductor processing system of claim 11, wherein the plasma generation means comprises a pair of external electrodes positioned around the chamber exterior.

13. The semiconductor processing system of claim 12, wherein the pair of external electrodes comprise an upper electrode positioned above the upper wall of the chamber body and a lower electrode positioned below the lower wall of the chamber body.

14. The semiconductor processing system of claim 12, wherein the pair of external electrodes comprises a first lateral electrode positioned proximate to an exterior surface of the first side wall and a second lateral electrode positioned proximate to an exterior surface of the second side wall opposing the first side wall.

15. The semiconductor processing system of claim 11, wherein the plasma generation means comprises one or more external coils extending around the chamber exterior between the injection flange and the substrate support.

16. The semiconductor processing system of claim 11, wherein the plasma generation means comprises a first external coil extending laterally around the chamber exterior and longitudinally proximate to the injection flange and a second external coil extending laterally around the chamber exterior and extending longitudinally proximate to the substrate support.

17. The semiconductor processing system of claim 1, wherein the injection flange further comprises a plurality of flow controllers configured to control a flow of the vapor phase process gas from a gas source assembly to the plurality of injection ports and therethrough to the chamber interior.

18. The semiconductor processing system of claim 17, wherein the gas source assembly comprises a silicon precursor source in fluid communication with the injection flange and wherein the reactive species comprise one or more of silicon radicals, silicon metastables, and silicon ions.

19. The semiconductor processing system of claim 1, wherein the chamber body has a plurality of external ribs extending laterally about a chamber exterior and longitudinally spaced apart from one another between the injection end and the longitudinally opposite exhaust end of the chamber body.

20. The semiconductor processing system of claim 19, further comprising a heater element array supported around the chamber exterior and optically coupled to the substrate support, the heater element array comprising:
a plurality of lower linear lamps supported below the chamber body and optically coupled to the substrate support by a quartz material forming the chamber body; and
a plurality of upper linear lamps supported above the chamber body and optically coupled to the substrate support by the quartz material forming the chamber body.

21. The semiconductor processing system of claim 20, further comprising a controller including a processor and a memory having instructions recorded on the memory that, when read by the processor, cause the processor to:
seat the substrate on the substrate support;
provide a controlled flow of the vapor phase process gas to the injection flange and therethrough to the chamber interior; and
activate the plasma generation means to generate the reactive species from the vapor phase process gas at the plasma generation zone to deposit one or more epitaxial layers onto the substrate.

22. A method for depositing an epitaxial layer on a substrate by a plasma assisted chemical vapor deposition process, the method comprising:
at a chamber body having an upper wall, a lower wall, a first side wall and a second side wall opposing the first side wall, wherein the upper wall extends longitudinally between an injection end and a longitudinally opposite exhaust end, and the lower wall is below and parallel relative to the upper wall;
seating the substrate on a substrate support arranged within a chamber interior between the injection end and the exhaust end;
introducing a vapor phase process gas into the chamber interior through an injection flange comprising a plurality of injection ports, the injection flange coupled to the injection end of the chamber body;
generating a reactive species within the chamber interior at a plasma generation zone disposed between the injection flange and the substrate support by activating a plasma generation means configured for decomposing the vapor phase process gas into the reactive species; and
depositing one or more epitaxial layers on the substrate.

23. The method of claim 22, further comprising heating the substrate to a deposition temperature employing a heater element array supported around a chamber exterior and optically coupled to the substrate support, the heater element array comprising:
a plurality of lower linear lamps supported below the chamber body and optically coupled to the substrate support by a quartz material forming the chamber body; and
a plurality of upper linear lamps supported above the chamber body and optically coupled to the substrate support by the quartz material forming the chamber body.
